(19) United States
(12) Patent Application Publication
(10) Pub. No.: US 2009/0221148 A1
(43) Pub. Date: Sep. 3, 2009

(54) PLASMA ETCHING METHOD, PLASMA ETCHING APPARATUS AND COMPUTER-READABLE STORAGE MEDIUM

(75) Inventors: Shuichiro Uda, Nirasaki City (JP); Yusuke Hirayama, Nirasaki City (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/393,466

(22) Filed: Feb. 26, 2009

Related U.S. Application Data
(60) Provisional application No. 61/048,409, filed on Apr. 28, 2008.

(30) Foreign Application Priority Data
Feb. 29, 2008 (JP) 2008-049500

(51) Int. Cl. H01L 21/311; H01L 21/3065

(52) U.S. Cl. 438/696; 156/345.24; 438/719; 257/E21.218; 257/E21.24

(57) ABSTRACT

A plasma etching method includes etching a single crystalline silicon layer of a substrate to be processed through a patterned upper layer formed on the single crystalline silicon layer by using a plasma of a processing gas, wherein forming a protection film at a sidewall portion of the upper layer by using a plasma of a carbon-containing gas is carried out before said etching the single crystalline silicon layer.

### FIELD OF THE INVENTION

The present invention relates to a plasma etching method for etching a single crystalline silicon layer by using a plasma of a processing gas, a plasma etching apparatus and a computer-readable storage medium.

### BACKGROUND OF THE INVENTION

Conventionally, in a manufacturing process of a semiconductor device, plasma etching is widely performed to etch single crystalline silicon forming a silicon wafer serving as a substrate to be processed by a plasma of a processing gas by using a photoresist as a mask.

In plasma etching of single crystalline silicon, a gaseous mixture of SF₆ and O₂ commonly used as a processing gas. However, in plasma etching of single crystalline silicon using a gaseous mixture of SF₆ and O₂ as a processing gas, an undercut may easily occur due to isotropic etching and it is difficult to achieve a vertical sidewall. Accordingly, etching is performed while a protection film is formed at the sidewall of the single crystalline silicon. Further, when single crystalline silicon is etched by using a silicon oxide film as a mask, etching is performed while a protection film is formed at the sidewall of the single crystalline silicon by adding silicon fluoride to the processing gas, thereby suppressing generation of the undercut (see, e.g., Patent Document 1).

Further, in plasma etching for etching an insulating film to form a contact hole, polymers are deposited at a sidewall portion of a silicon nitride film during etching of the silicon nitride film formed on the insulating film to reduce an opening dimension and the insulating film is etched by using the silicon nitride film as a mask, thereby forming a contact hole having a small diameter (see, e.g., Patent Document 2). However, this technique is for etching an insulating film such as an oxide film, but not for etching single crystalline silicon.

[Patent Document 1] Japanese Patent Laid-open Application No. 2004-87738

[Patent Document 2] Japanese Patent Laid-open Application No. H11-330245

As described above, in plasma etching of single crystalline silicon, conventionally, etching is performed while a protection film is formed at the sidewall of the single crystalline silicon by adding a silicon fluoride gas or the like to a processing gas for plasma etching, thereby suppressing generation of an undercut.

However, in the conventional technique, since a deposition gas is added to the processing gas, there was a problem of reducing an etching rate of single crystalline silicon.

### SUMMARY OF THE INVENTION

In view of the above, the present invention provides a plasma etching method capable of etching single crystalline silicon at a higher speed than a conventional method while preventing generation of an undercut, a plasma etching apparatus and a computer-readable storage medium.

In accordance with a first aspect of the present invention, there is provided a plasma etching method comprising: etching a single crystalline silicon layer of a substrate to be processed through a patterned upper layer formed on the single crystalline silicon layer by using a plasma of a processing gas, wherein forming a protection film at a sidewall portion of the upper layer by using a plasma of a carbon-containing gas is carried out before said etching the single crystalline silicon layer.

In the plasma etching method, a post-etching protection film removal of removing the protection film formed at the sidewall portion of the upper layer may be performed after said etching the single crystalline silicon layer.

In the plasma etching method, a pre-etching protection film removal of removing at least a portion of a protection film formed on the single crystalline silicon layer may be performed between said forming the protection film and said etching the single crystalline silicon layer.

In the plasma etching method, said etching the single crystalline silicon layer may be carried out by using a gaseous mixture of SF₆ and O₂ as the processing gas.

In the plasma etching method, a flow rate ratio of an O₂ flow rate to a total flow rate of the gaseous mixture may not be less than about 5%.

In the plasma etching method, said etching the single crystalline silicon layer may be carried out at a pressure equal to or higher than about 13.3 Pa.

In accordance with a second aspect of the present invention, there is provided a plasma etching apparatus comprising: a processing chamber for accommodating therein a substrate to be processed; a processing gas supply unit for supplying a processing gas into the processing chamber; a plasma generating unit for converting the processing gas supplied from the processing gas supply unit into a plasma to process the substrate; and a controller for allowing the plasma etching method of the first aspect to be performed in the processing chamber.

In accordance with a third aspect of the present invention, there is provided a computer-readable storage medium storing a control program executable on a computer, the control program controlling a plasma etching apparatus to perform the plasma etching method of the first aspect.

In accordance with the aspects of the present invention, it is possible to provide a plasma etching method capable of etching single crystalline silicon at a higher speed than a conventional case while preventing generation of an undercut, a plasma etching apparatus and a computer-readable storage medium.

### BRIEF DESCRIPTION OF THE DRAWINGS

The objects and features of the present invention will become apparent from the following description of embodiments given in conjunction with the accompanying drawings, in which:

FIGS. 1A to 1D are enlarged views showing a cross sectional configuration of a semiconductor wafer serving as a substrate to be processed in a plasma etching method in accordance with an embodiment of the present invention;

FIG. 2 illustrates a configuration of a plasma etching apparatus in accordance with the embodiment of the present invention;

FIG. 3 is a graph showing relationships between a pressure and an Si etching rate and between a pressure and a side etching value in a plasma etching process;

FIG. 4 is a graph showing a relationship between an Si etching rate and an O₂ flow rate ratio (O₂ flow rate/total flow rate); and

FIG. 5 is a cross sectional configuration of a semiconductor wafer in accordance with a modified embodiment.

### DETAILED DESCRIPTION OF THE EMBODIMENTS

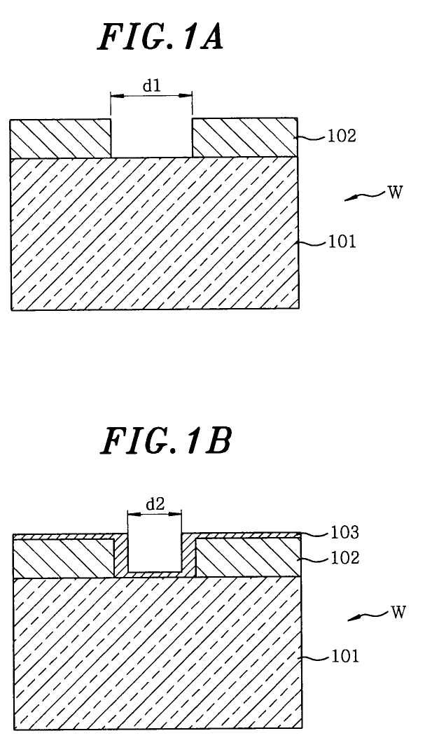

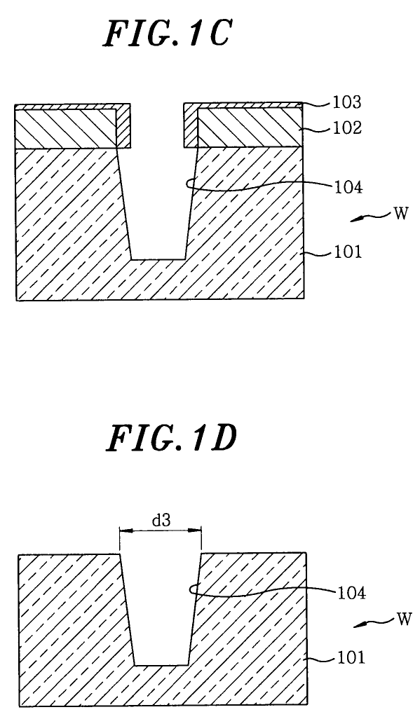

Hereinafter, embodiments of the present invention will be described in detail with reference to the accompanying drawings which form a part hereof. FIGS. 1A to 1D are enlarged views showing a cross sectional configuration of a semiconductor wafer serving as a substrate to be processed in a plasma etching method in accordance with an embodiment of the present invention. FIG. 2 illustrates a configuration of a plasma etching apparatus in accordance with the embodiment of the present invention. First, the configuration of the plasma etching apparatus will be described with reference to FIG. 2.

The plasma etching apparatus includes a processing chamber 1 which is airtightly sealed and electrically connected to a ground potential. The processing chamber 1 has a cylindrical shape and is made of, e.g., aluminum. A mounting table 2 serving as a lower electrode is provided in the processing chamber 1 to horizontally support the semiconductor wafer W serving as a substrate to be processed. The mounting table 2 is made of, e.g., aluminum and is supported by a support base 4 of a conductor through an insulating plate 3. A focus ring 5 is provided at an upper periphery of the mounting table 2. Further, a cylindrical inner wall member 3a made of, e.g., quartz is provided to surround the support base 4 of the mounting table 2.

The mounting table 2 is connected to a first RF power supply 10a via a first matching unit 11a and also connected to a second RF power supply 10b via a second matching unit 11b. The first RF power supply 10a for generating a plasma supplies a radio frequency power having a specific frequency (e.g., 27 MHz or more) to the mounting table 2. Further, the second RF power supply 10b for attracting ions supplies a radio frequency power having a specific frequency (13.56 MHz or less) lower than that of the first RF power supply 10a to the mounting table 2. Meanwhile, a shower head 16 connected to a ground potential is provided above the mounting table 2 to face the mounting table 2 in parallel. The mounting table 2 and the shower head 16 serve as a pair of electrodes.

An electrostatic chuck 6 for electrostatic adsorption of the semiconductor wafer W is provided on an upper surface of the mounting table 2. The electrostatic chuck 6 is configured by embedding an electrode 6a in an insulator 6b. The electrode 6a is connected to a DC power supply 12. Accordingly, when a DC voltage is applied to the electrode 6a from the DC power supply 12, the semiconductor wafer W is adsorbed to the electrostatic chuck 6 by a Coulomb force.

A coolant path 4a is formed in the support base 4. The coolant path 4a is connected to a coolant inlet line 4b and a coolant outlet line 4c. The support base 4 and the mounting table 2 can be controlled to have a predetermined temperature by circulating an appropriate coolant, e.g., cooling water in the coolant path 4a. Further, a backside gas supply line 30 for supplying a cold heat transfer gas (backside gas) such as a helium gas to a backside of the semiconductor wafer W is formed to pass through the mounting table 2 and the like. The backside gas supply line 30 is connected to a backside gas supply source (not shown). By providing this configuration, the semiconductor wafer W, which is adsorptively held on the upper surface of the mounting table 2 by the electrostatic chuck 6, can be controlled to be maintained at a predetermined temperature.

The shower head 16 is provided at a ceiling wall of the processing chamber 1. The shower head 16 includes a main body portion 16a and an upper ceiling plate 16b forming an electrode plate. The shower head 16 is supported by a support member 45 provided at an upper portion of the processing chamber 1. The main body portion 16a is made of a conductive material, e.g., anodically oxidized aluminum and is configured to detachably support the upper ceiling plate 16b provided under the main body portion 16a.

A gas diffusion space 16c is formed inside the main body portion 16a. Gas through holes 16d are formed at the bottom portion of the main body portion 16a to be positioned under the gas diffusion space 16c. Further, gas inlet holes 16e are formed in the upper ceiling plate 16b corresponding to the gas through holes 16d to pass through the upper ceiling plate 16b in its thickness direction. By providing this configuration, a processing gas supplied to the gas diffusion space 16c is supplied to be dispersed in a shower pattern into the processing chamber 1 via the gas through holes 16d and the gas inlet holes 16e. Further, a line (not shown) for circulating a coolant is provided at the main body portion 16a or the like so as to cool the shower head 16 to a desired temperature during a plasma etching process.

A gas inlet port 16f for introducing a processing gas into the gas diffusion space 16c is formed at the main body portion 16a. The gas inlet port 16f is connected to one end of a gas supply line 15a. The other end of the gas supply line 15a is connected to a processing gas supply source 15 for supplying a processing gas for etching (etching gas). Further, the gas supply line 15a is provided with a mass flow controller (MFC) 15b and a valve V1 sequentially from its upstream side. Further, for example, a gaseous mixture of a SF₆ gas and an O₂ gas, serving as a processing gas for plasma etching, is supplied to the gas diffusion space 16c from the processing gas supply source 15 through the gas supply line 15a. The gas is supplied to be dispersed in a shower pattern into the processing chamber 1 from the gas diffusion space 16c through the gas through holes 16d and the gas inlet holes 16e.

A cylindrical ground conductor 1a is provided at a higher position than a vertical position of the shower head 16 to extend upward from a sidewall of the processing chamber 1. The cylindrical ground conductor 1a has a ceiling wall at its upper portion.

A gas exhaust port 71 is formed at a bottom portion of the processing chamber 1. The gas exhaust port 71 is connected to a gas exhaust unit 73 via a gas exhaust pipe 72. The gas exhaust unit 73 has a vacuum pump which is operated such that the processing chamber 1 can be depressurized to a specific vacuum level. Meanwhile, a loading/unloading port 74 is provided at the sidewall of the processing chamber 1 such that the wafer W is loaded into or unloaded from the processing chamber 1 through the loading/unloading port 74. Further, a gate valve 75 for opening and closing the loading/unloading port 74 is provided at the loading/unloading port 74.

Reference numerals 76 and 77 of FIG. 2 designate detachable deposition shields. The deposition shield 76 is provided along an inner wall surface of the processing chamber 1. The deposition shield 76 prevents etching by-products (depositions) from being adhered to the processing chamber 1. A conductive member (GND block) 79, which is DC connected to ground, is provided at the deposition shield 76 at substantially the same position as the semiconductor wafer W, thereby preventing abnormal discharge.

An entire operation of the plasma etching apparatus having the above configuration is controlled by a controller 60. The controller 60 includes a process controller 61 having a CPU to control each component of the plasma etching apparatus, a user interface 62 and a storage unit 63.

The user interface 62 includes a keyboard for inputting commands, a display for displaying an operation status of the plasma etching apparatus or the like to allow a process manager to manage the plasma etching apparatus.

The storage unit 63 stores recipes including control programs (software) for implementing various processes in the plasma etching apparatus under control of the process controller 61, process condition data and the like. If necessary, as a certain recipe is retrieved from the storage unit 63 in accordance with an instruction inputted through the user interface 62 and executed in the process controller 61, a desired process is performed in the plasma etching apparatus under control of the process controller 61. Further, the recipes including control programs, process condition data and the like can be stored in and retrieved from a computer-readable storage medium such as a hard disk, a CD-ROM, a flexible disk and a semiconductor memory, or retrieved through an on-line connected via, for example, a dedicated line to another apparatus available all the time.

Next, steps for plasma etching single crystalline silicon of the semiconductor wafer W in the plasma etching apparatus having the above configuration will be described. First, the gate valve 75 is opened and, then, the semiconductor wafer W is loaded into the processing chamber 1 from the loading/unloading port 74 through a load-lock chamber (not shown) by using a transfer robot (not shown) to be mounted on the mounting table 2. Then, the transfer robot is retracted from the processing chamber 1 and the gate valve 75 is closed. Then, the processing chamber 1 is evacuated through the gas exhaust port 71 by using the vacuum pump of the gas exhaust unit 73.

After the processing chamber 1 is maintained to have a predetermined vacuum level, a specific processing gas (etching gas) is introduced into the processing chamber 1 from the processing gas supply source 15. When the processing chamber 1 is maintained at a predetermined pressure of, e.g., 26.6 Pa (200 mTorr), a radio frequency power having a high frequency is supplied to the mounting table 2 from the first RF power supply 10a. Further, a radio frequency power having a frequency lower than that of the first RF power supply 10a is supplied to the mounting table 2 from the second RF power supply 10b to attract ions. In this case, a specific DC voltage is applied to the electrode 6a of the electrostatic chuck 6 from the DC power supply 12, so that the semiconductor wafer W is adsorbed to the electrostatic chuck 6 by a Coulomb force.

In this case, when a radio frequency power is applied to the mounting table 2 serving as a lower electrode as described above, an electric field is formed between the shower head 16 serving as an upper electrode and the mounting table 2 serving as a lower electrode. Accordingly, discharge occurs in the processing space including the semiconductor wafer W, and a plasma of the processing gas is generated to thereby etch the silicon, such as polysilicon and amorphous silicon, formed on the semiconductor wafer W.

Further, when the etching process has been completed, supplies of the radio frequency power and the processing gas are stopped and the semiconductor wafer W is unloaded from the processing chamber 1 in a sequence opposite to the above-described sequence.

Next, a plasma etching method using the aforementioned plasma etching apparatus in accordance with the embodiment of the present invention will be described with reference to FIGS. 1A to 1D. FIGS. 1A to 1D illustrate enlarged views showing main parts of the semiconductor wafer W serving as a substrate to be processed in accordance with the embodiment of the present invention. As shown in FIG. 1A, a photoresist layer 102 having a specific pattern is formed on a surface of a single crystalline silicon layer 101 of the semiconductor wafer W.

In the embodiment of the present invention, first, as shown in FIG. 1B, a protection film forming process is performed to form a protection film 103 mainly at a sidewall portion of the pattern of the photoresist layer 102. The protection film 103 is formed of a material which is hardly etched in plasma etching of the single crystalline silicon layer 101 to be described later. In this case, an organic film is formed as the protection film 103 by using a plasma of a carbon-containing gas, for example, a CF-based gas (e.g., C₄F₈).

In a case using a C₄F₈ gas, a pressure ranges preferably from 6.65 to 133 Pa (50 to 1000 mTorr), more preferably, from 13.3 to 53.2 Pa (100 to 400 mTorr). Further, a gas flow rate ranges preferably from 50 to 1000 sccm, more preferably, 300 to 600 sccm. Further, if necessary, another gas such as a CH₄ gas may be added thereto. When a CH₄ gas is added, the protection film 103 can be formed to be carbon-rich and strong against fluorine radicals.

Further, a radio frequency power having a high frequency for generation of plasma, which is applied from the first RF power supply 10a, has a voltage ranging preferably from 1000 V to 3000 V, more preferably, about 2000 V. Meanwhile, a radio frequency power having a low frequency for bias, which is applied from the second RF power supply 10b, has a voltage ranging preferably from 100 V to 1000 V, more preferably, about 200 V. Further, the time required for the protection film forming process is about 5 to 120 seconds.

It is preferable that the protection film 103 formed at the sidewall portion of the pattern of the photoresist layer 102 has a thickness of 0.5 μm or more. The protection film 103 is also formed on the surface of the photoresist layer 102 and on the surface of the single crystalline silicon layer 101 at a bottom portion of the pattern of the photoresist layer 102. In this case, it is preferable that the protection film 103 formed on the surface of the single crystalline silicon layer 101 has a thin thickness, preferably, smaller than 0.1 μm. In order to thickly form the protection film 103 at the sidewall portion of the pattern and to thinly form the protection film 103 at the bottom portion of the pattern, a bias voltage applied from the second RF power supply 10b is adjusted such that the protection film is more deposited on the sidewall than the bottom portion by sputtering.

Further, when the protection film 103 formed on the surface of the single crystalline silicon layer 101 (bottom portion of the pattern) has a thickness equal to or larger than 0.1 μm, before a plasma etching process of the single crystalline silicon layer 101, preferably, a pre-etching protection film removal process is performed to remove at least a portion of the protection film 103 formed on the surface of the single crystalline silicon layer 101. Accordingly, the single crystalline silicon layer 101 can be quickly etched in the plasma etching process of the single crystalline silicon layer 101. The pre-etching protection film removal process may be performed in the same way as a post-etching protection film removal process to be described later. However, in the pre-etching protection film removal process, the protection film 103 formed on the surface of the single crystalline silicon layer 101 (bottom portion of the pattern) is mainly removed. Thus, it is preferable to increase a voltage of a radio frequency power having a low frequency for bias, which is applied from the second RF power supply 10b, to some extent.

Then, as shown in FIG. 1C, plasma etching of the single crystalline silicon layer 101 is performed by using, as a mask, the photoresist layer 102 having the protection film 103 at the sidewall portion of the pattern to thereby form a hole or trench 104 in the photoresist layer 102 corresponding to the mask. In the plasma etching process of the single crystalline silicon layer 101, a gaseous mixture of SF₆ and O₂ is used as a processing gas.

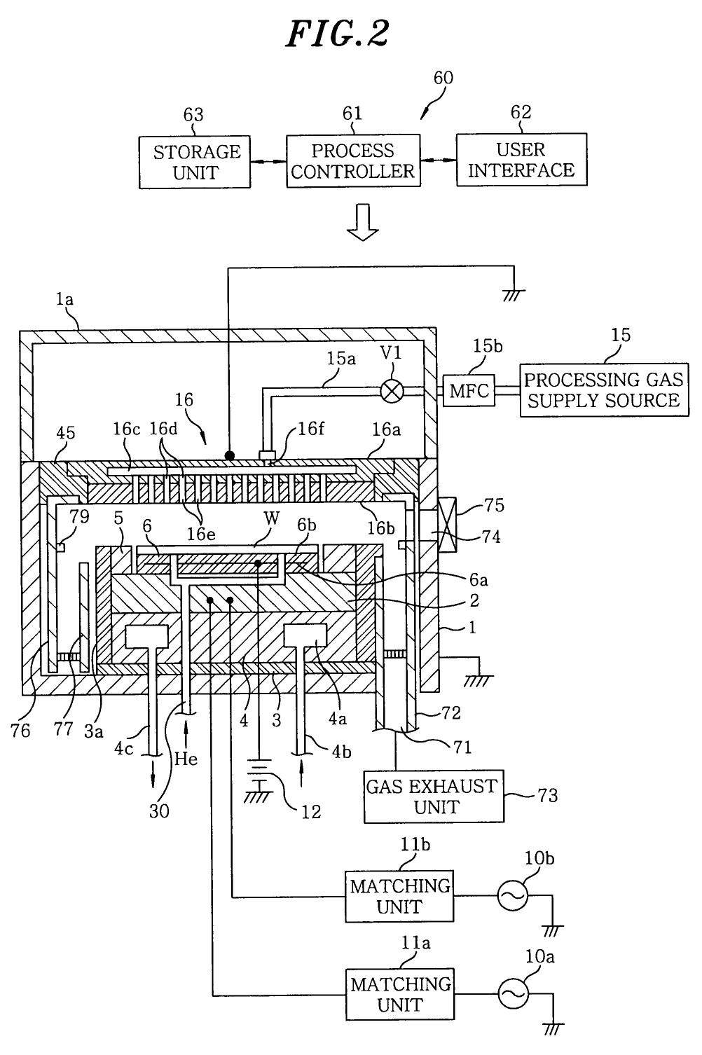

FIG. 3 is a graph showing relationships between a pressure and an Si etching rate and between a pressure and a side etching value in a plasma etching process using a gaseous mixture of SF₆ and O₂ as a processing gas, wherein vertical axes represent an Si etching rate and a side etching value and a horizontal axis represents a pressure. As shown in the graph of FIG. 3, in the plasma etching process, as the pressure increases, the Si etching rate increases and the side etching value also increases. Accordingly, in order to achieve high-speed etching at a high etching rate in the plasma etching process, the pressure ranges preferably from 13.3 to 133 Pa (100 to 1000 mtorr), more preferably, about 26.6 Pa (200 mTorr). In this case, although the side etching value also increases, the protection film 103 formed in advance at the sidewall portion of the photoresist layer 102 reduces an influence of side etching on a final etching shape.

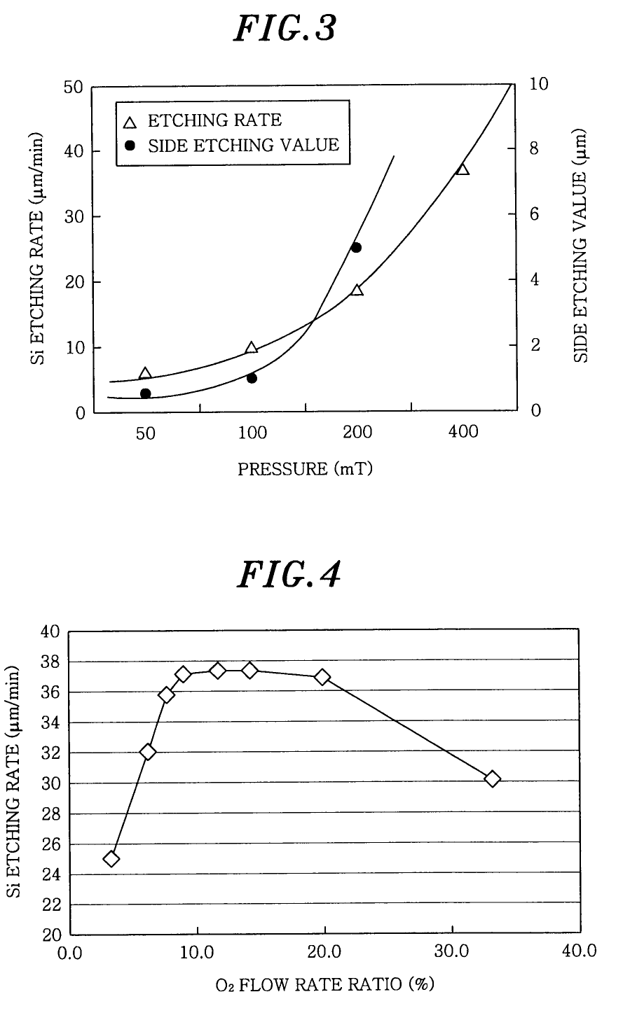

Further, the gas flow rate of the SF₆ gaseous mixture ranges preferably from 100 to 1000 sccm, more preferably, about 400 sccm. Further, the gas flow rate of an O₂ gas ranges preferably from 10 to 500 sccm, more preferably, about 80 sccm. Further, if necessary, another gas such as CF₄ and N₂ may be added to the gaseous mixture. FIG. 4 is a graph showing a relationship between an Si etching rate and an O₂ flow rate ratio, wherein a vertical axis represents an Si etching rate and a horizontal axis represents an O₂ flow rate ratio. As shown in the graph of FIG. 4, when an O₂ flow rate ratio increases to some extent, the Si etching rate increases. When an O₂ flow rate ratio exceeds a specific value, the Si etching rate decreases on the contrary. Accordingly, it is preferable that an O₂ flow rate ratio (O₂ flow rate/total flow rate) ranges from 5% to 50%.

Further, a voltage of a radio frequency power having a high frequency for plasma generation, which is applied from the first RF power supply 10a, ranges preferably from 500 to 3000 V, more preferably, about 1500 V. On the other hand, a voltage of a radio frequency power having a low frequency for bias, which is applied from the second RF power supply 10b, ranges preferably from 0 to 1000 V, more preferably, about 100 V. The time required for plasma etching process is about 30 to 1200 seconds.

Then, a post-etching protection film removal process is performed to remove the photoresist layer 102 and the protection film 103 as shown in FIG. 1D. The process may be performed by oxygen plasma ashing using an O₂ gas as a processing gas. In this case, in the post-etching protection film removal process, the pressure ranges preferably from 13.3 to 106 Pa (100 to 800 mTorr), more preferably, about 26.6 Pa (200 mTorr). Further, a gas flow rate of the O₂ gas ranges preferably from 200 to 2000 sccm, more preferably, about 600 sccm. Further, if necessary, another gas such as CF₄ and N₂ may be added to the gaseous mixture.

Further, a voltage of a radio frequency power having a high frequency for plasma generation, which is applied from the first RF power supply 10a, ranges preferably from 500 to 3000 V, more preferably, about 1000 V. On the other hand, a voltage of a radio frequency power having a low frequency for bias, which is applied from the second RF power supply 10b, ranges preferably from 0 to 500 V, more preferably, about 100 V. The time required for the post-etching protection film removal process is about 0 to 300 seconds.

As described above, in the embodiment of the present invention, plasma etching of the single crystalline silicon layer 101 is performed by using, as a mask, the photoresist layer 102 having the protection film 103 formed at the sidewall portion of the pattern in the protection film forming process. Accordingly, plasma etching of the single crystalline silicon layer 101 can be performed at a high etching rate. Thus, although side etching occurs at a portion right under the photoresist layer 102 of the single crystalline silicon layer 101, since an opening of the pattern has a small dimension (represented by d2 in FIG. 1B) by the protection film 103 formed in advance, a dimension (represented by d3 in FIG. 1D) of a side etched portion can approach a dimension (represented by d1 in FIG. 1A) of an initial pattern.

That is, the protection film 103 is formed in advance at the sidewall portion of the photoresist layer 102. Therefore, an undercut due to side etching generated right under the photoresist layer 102 has little influence on a final etching shape.

As an experimental example, plasma etching of the single crystalline silicon layer 101 was performed at a pressure of 26.6 Pa (200 mTorr) and at an O₂ flow rate ratio of 21%. Accordingly, the single crystalline silicon layer 101 was etched at a high etching rate of 31 μm/min. Further, an undercut (enlargement of d3 to d1) due to side etching was approximately zero.

As described above, in accordance with the embodiment of the present invention, it is possible to etch single crystalline silicon at a higher speed than a conventional method while preventing generation of an undercut. Further, the present invention may be modified without being limited to the above-described embodiment. For example, the plasma etching apparatus may employ various plasma etching apparatuses such as an upper-and-lower plate dual frequency application type plasma etching apparatus or a lower plate single frequency application type plasma etching apparatus without being limited to a parallel plate type and lower plate dual frequency application type plasma etching apparatus shown in FIG. 2.

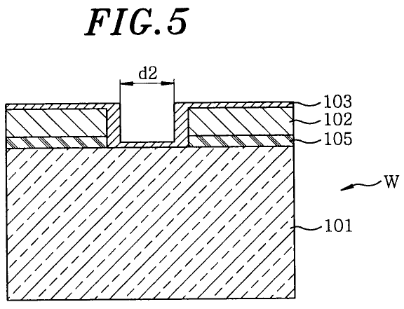

Further, although the photoresist layer 102 is formed on the single crystalline silicon layer 101 in the above embodiment, as shown in FIG. 5, a layer made of a different material, for example, a multilayer film 105 may be interposed between the single crystalline silicon layer 101 and the photoresist layer 102. In this case, after etching the multilayer film 105, the protection film 103 is formed at a sidewall portion of the photoresist layer 102 and a sidewall portion of the multilayer film 105. Then, etching of the single crystalline silicon layer 101 is carried out. Further, a patterned layer formed on the single crystalline silicon layer 101 may be a hard mask layer made of a different material without being limited to the photoresist layer 102.

While the invention has been shown and described with respect to the embodiments, it will be understood by those skilled in the art that various changes and modifications may be made without departing from the scope of the invention as defined in the following claims.

What is claimed is:

1. A plasma etching method comprising:
etching a single crystalline silicon layer of a substrate to be processed through a patterned upper layer formed on the single crystalline silicon layer by using a plasma of a processing gas,
wherein forming a protection film at a sidewall portion of the upper layer by using a plasma of a carbon-containing gas is carried out before said etching the single crystalline silicon layer.

2. The plasma etching method of claim 1, wherein a post-etching protection film removal of removing the protection film formed at the sidewall portion of the upper layer is performed after said etching the single crystalline silicon layer.

3. The plasma etching method of claim 1, wherein a pre-etching protection film removal of removing at least a portion of a protection film formed on the single crystalline silicon layer is performed between said forming the protection film and said etching the single crystalline silicon layer.

4. The plasma etching method of claim 1, wherein said etching the single crystalline silicon layer is carried out by using a gaseous mixture of SF₆ and O₂ as the processing gas.

5. The plasma etching method of claim 4, wherein a flow rate ratio of an O₂ flow rate to a total flow rate of the gaseous mixture is not less than about 5%.

6. The plasma etching method of claim 4, wherein said etching the single crystalline silicon layer is carried out at a pressure equal to or higher than about 13.3 Pa.

7. A plasma etching apparatus comprising:
a processing chamber for accommodating therein a substrate to be processed;
a processing gas supply unit for supplying a processing gas into the processing chamber;
a plasma generating unit for converting the processing gas supplied from the processing gas supply unit into a plasma to process the substrate; and
a controller for allowing the plasma etching method described in claim 1 to be performed in the processing chamber.

8. A computer-readable storage medium storing a control program executable on a computer, the control program controlling a plasma etching apparatus to perform the plasma etching method described in claim 1.
